(19) United States
(12) Patent Application Publication
(10) Pub. No.: US 2011/0266580 A1
(43) Pub. Date: Nov. 3, 2011

(54) LIGHT SOURCE COMPRISING A LIGHT RECYCLING DEVICE AND CORRESPONDING LIGHT RECYCLING DEVICE

(75) Inventors: Celine C. S. Nicole, Eindhoven (NL); Clemens J. M. Lasance, Nuenen (NL)

(73) Assignee: KONINKLIJKE PHILIPS ELECTRONICS N.V., Eindhoven (NL)

(21) Appl. No.: 13/145,356

(22) PCT Filed: Jan. 18, 2010
(86) PCT No.: PCT/IB2010/050220

§ 371 Date: Jul. 20, 2011

(30) Foreign Application Priority Data
Jan. 21, 2009 (EP) 09151019.8

(51) Int. Cl. H01L 33/50

(52) U.S. Cl. 257/98; 257/E33.061

(57) ABSTRACT

The invention relates to a light source (1) comprising a light-emitting device (3) and a light recycling device (5), said light recycling device (5) is located in an optical path (7) of the light-emitting device (3). The light recycling device (5) comprises at least one light recycling member (9) for changing at least one physical property of light passing it and at least one thermally conductive member (10, 11) capable of conducting heat generated in the light recycling member (9), said thermally conductive member (10, 11) is in thermal contact with the light recycling member (9) and at least one heat sink (12).

The invention further relates to a light corresponding recycling device (5).

### FIELD OF THE INVENTION

The invention relates to a light source comprising a light-emitting device and a light recycling device, said light recycling device is located in an optical path of the light-emitting device.

### BACKGROUND OF THE INVENTION

A light source comprising a light-emitting device and a light recycling device is known for example as a light source comprising a Light Emitting Diode (LED) emitting blue light and/or ultraviolet light and a light recycling device comprising a phosphor plate in the an optical path of the LED for converting the wavelength of one part of the light into yellow light to generate white light. The luminance of said light source is limited by the thermal conductivity of the material(s) used within the light recycling device.

In the management of electronics cooling, composite materials are widely used to improve thermal conductivity. They could be used to manufacture heat sinks, or included in packaging or as layer in semiconductor devices, printed circuit boards, etc. In the present field the light recycling material has to be adequate to recycle light even in the focus of a high luminance light-emitting device.

### SUMMARY OF THE INVENTION

It is an object of the invention to provide a light source comprising a light-emitting device and a light recycling device arranged in the optical path of the light-emitting device with an enhanced thermal application range.

To achieve this object, the light recycling device comprises at least one light recycling member for changing at least one physical property of light passing it and at least one thermally conductive member capable of conducting heat generated in the light recycling member, said thermally conductive member is in thermal contact with the light recycling member and at least one heat sink.

Preferably the light-emitting device is a high luminance light-emitting device with a luminance not less than 1·10⁷ cd/m² (≧10 candela per square millimeter equivalent to 10 mega nit: 10 Mcd/m²) and/or a laser (laser: light amplification by stimulated emission of radiation). The brightness (luminance) of a laser is at least a factor 100 higher than the brightness reachable with conventional LEDs (˜10⁹ cd/m² versus ˜10² cd/m²). The laser is preferably a solid state laser and/or laser diode.

In one embodiment of the invention, the change of the physical property of light is a wavelength converting of the light and/or a change of the polarization state of the light. The light recycling member for changing the polarization state of the light is especially a retarding member or a depolarization member.

According to another embodiment, the light recycling member is a phosphor plate and/or a phosphor film. The phosphor plate and/or phosphor film is a commonly known wavelength converting light recycling member. At the same time, the phosphor plate and/or phosphor film is a light recycling member changing the polarization state of the light. The light or the light beam emitted by the light emitting device is used for pumping said phosphor plate and/or phosphor film. The phosphor plate and/or phosphor film is preferably made of a cerium doped yttrium aluminum garnet phosphor or ceramic phosphor, especially a “lumiramic” ceramic phosphor with additional doping elements (such as Cerium or Erbium).

While those can withstand high temperatures, recent experiments have shown that the phosphor ceramic conversion properties are sensitive to temperature. High temperature can be reached in a focal spot of the high luminance light-emitting device and/or laser where the power density reaches several kW/cm². This focal spot is generally located within the phosphor plate or phosphor film of the light recycling device. A decrease in light intensity emission with CECAS type ceramic has been observed in this experiment around 150° C. with a strong decrease in the decay time starting from 350° C. When the ceramic is heated, efficiency strongly decreases, this situation will happen with e.g. a 1 Watt laser.

This dependency with temperature in the focal spot reduces the ultimate efficiency of such light source and can be a strong technology limitation. One of the main causes has been recently identified as being the very low thermal conductivity of the phosphor material. The thermal conductivity of the ceramic has a very strong impact on the maximum hotspot temperature.

In another embodiment of the invention, the light-emitting device is a light-emitting device emitting blue light and/or ultraviolet light. The blue light and/or ultraviolet light emitted by the light-emitting device is used for pumping the phosphor plate or the phosphor film—preferably made of a cerium doped yttrium aluminum garnet phosphor and/or ceramic phosphor—to create white light leaving the phosphor plate or the phosphor film.

In yet another embodiment, the thermally conductive member is a light polarizing member. Light polarizing members are based on absorptive polarizers (like wire-grid polarizers) and/or beam-splitting polarizers (like reflective polarizers, birefringent polarizers and/or thin film polarizers). Especially, the light polarizing member is covering one complete surface of the light recycling member.

Typical applications where polarized light is used are in LCD-backlighting and LCD-projection (LCD: liquid crystal display) as well as in options for LC-beam steering devices in which the light beam emitted by LED point sources is manipulated with LC cells (LC: liquid crystal). Also, polarized light yields advantages in both indoor and outdoor illumination as linearly polarized light influences reflections on surfaces which enable the suppression of glare and the subsequent influencing of observation of the illuminated surrounding in visual acuity, observed contrast and color saturation. Because of this influence, polarizing fluorescent luminaries exist as commercial products with a claimed benefit in visual perception.

According to a preferred embodiment of the invention, the light polarizing member is a wire-grid polarizer. Using advanced lithographic techniques, very tight pitch metallic grids can be made which polarize visible light.

In another embodiment, the thermally conductive member of the light recycling device is formed as a thermally conductive layer arranged on a surface of the light recycling member and/or in between two different parts of the light recycling member. Especially two thermally conductive layers are arranged on two surfaces of the light recycling member, said surfaces opposing each other.

According to a preferred embodiment, the thermally conductive layer is an at least partial reflective layer. Especially, one of the two thermally conductive layers arranged on the two surfaces opposing each other is a light polarizing member formed as a light polarizing layer and the other layer is an at least partial reflective layer.

According to another preferred embodiment, the thermally conductive member is a diamond member and/or a sapphire member. Especially, the thermally conductive member or at least one of the thermally conductive members is a diamond layer and/or a sapphire layer. The diamond layer is preferably a diamond layer produced through CVD diamond growth (CVD: chemical vapor deposition). The high thermal conductivity of diamond enables thin-film diamond coatings or layer diamond coatings to improve thermal management photonic and microelectronic devices.

The thermally conductive layer formed as a diamond layer solves the thermal problem by increasing the local thermal conductivity of a material. It proposes the insertion of a layer material with optimum thickness which would be sufficient to increase the equivalent global thermal conductivity by the factor two (up to 1400 W/mK).

This embodiment proposes a solution such that the light recycling device formed as a phosphor ceramic (Ce:YAG) can be thermally enhanced to allow light to be generated with a power density up to 16 kW/cm². In that case the hottest spot reaches 310° C. which should be reasonable to allow a maximum of light conversion in the material. The ceramic can be of all different sorts of ceramics, especially poly ceramics and/or single crystal ceramics, which are strongly scattering or transparent.

Preferably, the light source further comprises an optical element arranged between the light-emitting device and the light recycling device. The optical element is located in the optical path of the light-emitting device. Especially the optical element is a light focusing element, focusing the light emitted by the light-emitting device within the light recycling member.

In another embodiment, the light recycling device further comprises the heat sink. A light source with a light recycling device comprising the light recycling member, the thermally conductive member and the heat sink is very compact. Additionally or in another embodiment, the light recycling device further comprises a thermoelectric element and/or Peltier element for cooling the thermally conductive member, especially the wires of the wire-grid polarizer.

According to another preferred embodiment, the light recycling member and the thermally conductive member build a composite material of the light recycling device.

The invention further relates to a light recycling device for changing at least one physical property of light passing it. The light recycling device comprises at least one light recycling member and at least one thermally conductive member capable of conducting heat generated in the light recycling member, wherein said thermally conductive member is in thermal contact with the light recycling member and the heat sink.

The change of the physical property of the light is preferably a change of the color and/or a change of the polarization. More preferably, the light recycling member is formed as a phosphor plate or a phosphor film—preferably made of a cerium doped yttrium aluminum garnet phosphor or ceramic phosphor—to create white light leaving the phosphor plate or the phosphor film, when the light recycling member is located in an optical path of a light-emitting device emitting blue light and/or ultraviolet light.

In another embodiment, the thermally conductive member is a light polarizing member. According to a preferred embodiment of the invention, the light polarizing member is a wire-grid polarizer.

According to another preferred embodiment, the thermally conductive member is a diamond member and/or a sapphire member.

Especially, the light recycling device further comprises the heat sink.

### BRIEF DESCRIPTION OF THE DRAWINGS

These and other aspects of the invention will be apparent from and elucidated with reference to the embodiments described hereinafter.

In the drawings:

FIG. 1A is a side view of a light source for emitting polarized light comprising a light-emitting device and a light recycling device according to a first embodiment of the invention;

FIG. 1B is a top view of the light source for emitting polarized light according to FIG. 1A;

FIG. 2 is a side view of a light recycling device of a light source according to a second embodiment of the invention; and

FIG. 3 is a side view of a light recycling device of a light source according to a third embodiment of the invention.

### DETAILED DESCRIPTION OF EMBODIMENTS

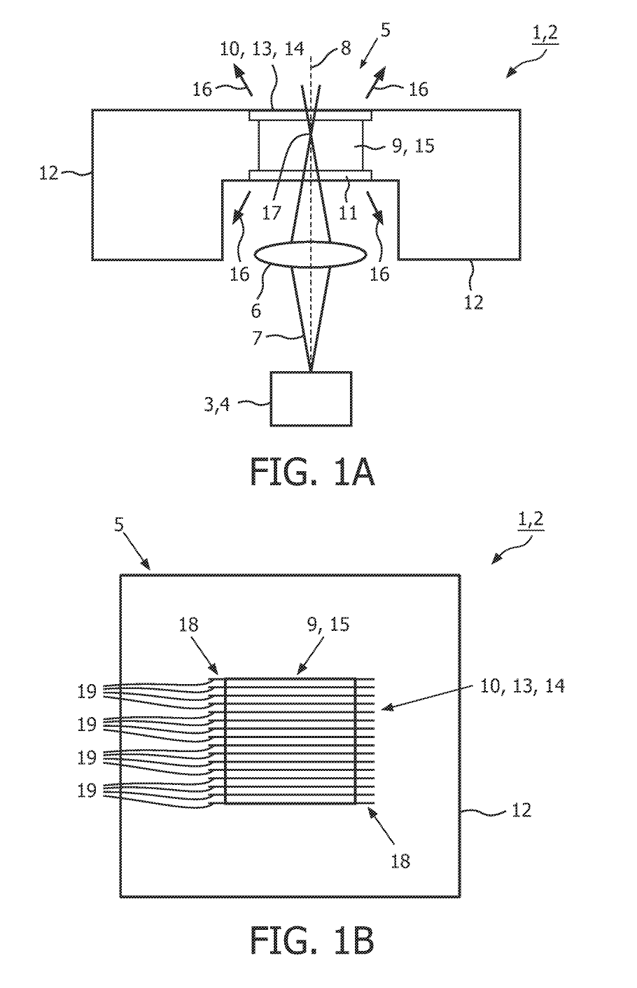

FIG. 1A shows a light source 1 formed as a light source for emitting polarized light 2. The light source 1 comprises a light-emitting device 3 formed as a laser (light amplification by stimulated emission of radiation) 4 emitting light (laser light), a light recycling device 5 and an optical element 6. The light recycling device 5 and the optical device 6 are arranged in an optical path 7 of the light emitting-device 3, wherein the optical element 6 is a convex lens arranged between the light-emitting device 3 and the light recycling device 5. The optical path 7 has a main axis 8.

The light recycling device 5 comprises a light recycling member 9 for changing at least one physical property of light passing it, two thermally conductive members 10, 11 capable of conducting heat generated in the light recycling member 9 and a heat sink 12 formed as a frame encompassing the light recycling member 9. One of the thermally conductive members 10 is located on a first surface of the light recycling member 9; said first surface is facing the optical device 6 and the light-emitting device 3. The other thermally conductive member 11 is located on a second surface of the light recycling member 9; said second surface is located on the opposite side of the light recycling member 9 to the first surface. Both thermally conductive members 10, 11 are arranged perpendicular to the main axis 8 of the optical path 7.

The thermally conductive members 10, 11 are formed as light polarizing members 13, especially wire-grid polarizers 14. The light recycling member 9 of the embodiment shown in FIGS. 1A and 1B is a phosphor film 15. The phosphor film 15 is a light recycling member 9 for wavelength converting of the light passing it.

The laser 4 is emitting blue light and/or ultraviolet light. The blue light and/or ultraviolet light emitted by the laser 4 is used for pumping the phosphor film 15—preferably made of a cerium doped yttrium aluminum garnet phosphor (YAG phosphor) or ceramic phosphor—to create white light leaving the phosphor film 15 (arrows 16). A hot spot is created within the focal spot 17 of the optical path 7. This hot spot is located in the light recycling member 9.

The essential feature of this embodiment of the invention is to use a light polarizing member 13 (formed as a wire-grid polarizer 14) deposited on the surfaces of the phosphor film 15 (or a phosphor plate) to allow cooling and heat dissipation of the hotspot created by blue light and/or ultraviolet light emitted by the light-emitting device 3. Depending on the configuration adopted, gain in polarized light output can be obtained if the back reflected and non-converted light return to the light emitting device 3. In case recycling is intended by the embodiment, in order to allow the reflected polarization to pass the light polarizing member 13 formed as a wire-grid polarizer 14 again. In general, the polarized light has to be retarded with a retarding layer. In this embodiment the retarding layer role is already fulfilled by the phosphor film 15 (or phosphor plate). In this case the efficiency will be increased compared to a single passage of the light which has too much absorption (50 to 55% at best).

The wire-grid polarizer 14 is made of metal, especially aluminum or silver or gold, and has a very high conductivity and allows the heat to flow very efficiently towards the sides 18 where the wires 19 of the wire-grid polarizer 14 are in thermal contact with a bigger heat sink 10. FIG. 1B shows a top view of the light source for emitting polarized light of FIG. 1A.

A laser focal spot 17 of 30 by 30 microns is focused within the phosphor plate or phosphor film 15, said laser 4 with a total power of 1 Watt. Thanks to the wire-grid polarizer 14 on the surface of the phosphor plate or phosphor film 15, the temperature of a light recycling device is decreased from 345° C. to 177° C. at the centre of the laser beam on the second surface (thermal power dissipation of 200 mW), The second surface (top surface in FIG. 1A) is where the light absorption is the strongest and therefore a decrease in temperature at the surface will induce the highest gain in light conversion. With the wire grid polarizers 14 the hottest spot is moved further down the YAG ceramic. The wire-grid polarizer 14 is positioned only on a surface covering the laser spot (32 μm width). Additional wires 19 would improve slightly the cooling.

These results show that an addition of a wire-grid polarizer 14 would improve temperature of the hotspot. In the particular case, it will make the difference between a fully efficient light conversion and a conversion limited by temperature (for CECAS efficiency drop when temperature reaches about 350° C.).

It is important to realize that the wires 19 of the wire grid polarizer 14 outside the optical path 7 have different thickness, are especially thicker, than in the region in the optical path (not shown) and be joined together with a welding tape and/or other fasteners. This makes the light recycling device 5 easy to manufacture.

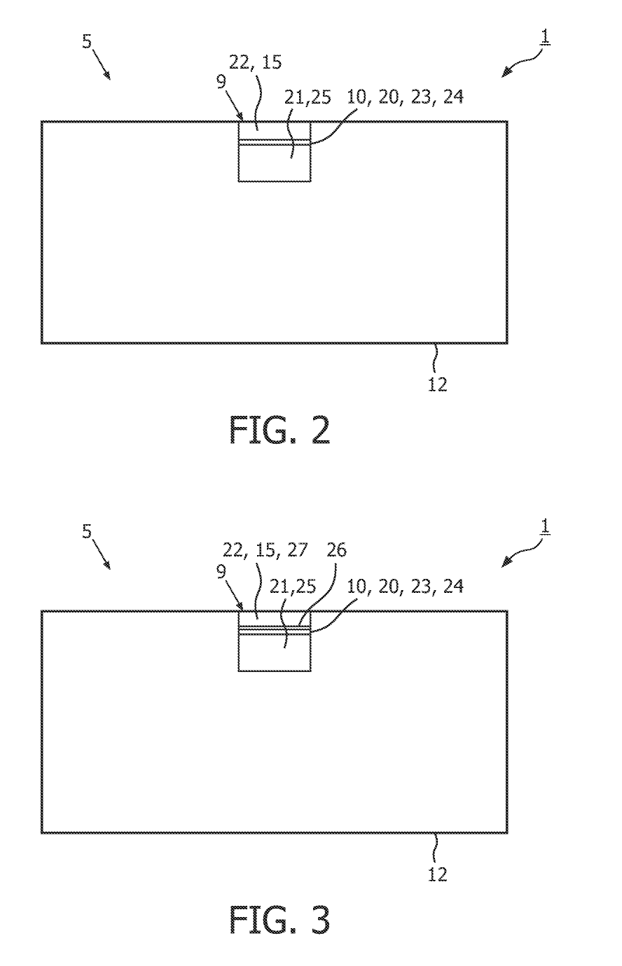

FIG. 2 is a side view of a light recycling device 5 of a light source 1 according to a second embodiment of the invention. The thermally conductive member 10 is formed as a thermally conductive layer 20 arranged in between two different parts 21, 22 of the light recycling member 9. The thermally conductive layer 20 is formed as a diamond member 23, especially a diamond layer 24.

The method for producing the light recycling device 5 comprises the steps of:
application of the diamond layer 24 to a surface of the first part 21 of the light recycling member 9, especially the first part 21 formed as a phosphor plate 25,
application of a second part 22, especially a phosphor film 15, onto the surface of the diamond layer 24,
cutting the composite device of first part 21, diamond layer 24, and second part 22 into the final form as used in the light recycling member 9 and
assembling the composite device and the heat sink 12.

Especially, the diamond layer 24 is deposited by CVD on the phosphor plate 25, in particular a YAG ceramic phosphor plate. Next, a thin phosphor film 15 deposition is made on the diamond layer 24. This can be done with thickness going from 10 to 50 micrometers. The composite device is then cut using cutting tools and inserted in a copper heat sink 12.

The embodiment solves a thermal problem by increasing the local thermal conductivity of the light recycling material. It proposes the insertion of a diamond layer 24 with optimum thickness which would be sufficient to increase by two the equivalent global thermal conductivity.

In the specific case of a ceramic phosphor plate 25 of 100 by 100 micron and 150 micron thick, and with a laser beam of 30 micron spot size and a power density (in the hottest spot) of 16 kW/cm2 a diamond layer 24 of 10 micron thickness 100 by 100 micron wide is inserted (so that the layer is in contact with the heat sink 12). This diamond layer 24 is positioned in the material at a distance of 20 microns from the top surface as shown in FIG. 2.

We consider a certain bulk phosphor plate 25 which size can vary (example Ce:YAG) and with a thermal conductivity of 3 W/mK. This phosphor material 15, 25 of the plate 23 is surrounded (except for the top to allow the laser beam to interact and light to be extracted) by a heat sink 12, especially made of copper.

In a different configuration (not shown) where six clusters of 10×10 micron diamond are uniformly spread through the phosphor material. In this way a composite material is realized. Only two of these clusters are touching the walls of the heat sink 12 (which is important for cooling). The improvement is insignificant in that case. However it is not really possible to model this way a real composite material. There are strong dependences of shape and the size of the particles, especially in the range of nanometer size particles. Thermal conductivity of composite material will also be dependent of the volume fraction. We could assume that similar order of magnitude can be compared with existing composite material (like diamond-copper). In those types of composite materials, thermal conductivity could be almost doubled (to 742 W/mK). But this case needs quite a high volume ratio of diamond. The ratio is starting from 50% to 90%. This might be too high for wavelength converting since the phosphor material is used to generate white light; this means that the phosphor should stay the same as much as possible. Too many of other particles might decrease the photonic properties.

FIG. 3 shows a side view of a light recycling device 5 of a light source 1 according to a third embodiment of the invention. A diamond layer 24 is deposited on a phosphor plate 25 of 100 to 150 micron thickness. A thin glue layer 26 on the diamond layer 24 connects another phosphor plate 27 (thick enough to be mechanically solid). Afterwards the other side of the other phosphor plate 27 is grinded to get 20 micrometer thick phosphor film 15 (YAG layer).

The method differs from the above mentioned method in that the application of a second part 22 is an adhesive bonding of the second part and a subsequently production of the phosphor film 15 by grinding.

Alternatively the diamond layer 23 is not sandwiched but deposited on the top surface of the ceramic (not shown). In order to have sufficient heat transfer the surface contact of the diamond layer 24 and the heat sink 12 should be increased. This could be achieved by doing the CVD process of a ceramic. Then, individual pieces of ceramics can be cut and inserted in a copper block of appropriate size to optimize the surface contact.

In conclusion, the technique can be applied for handling high temperature hotspots of laser light in phosphor materials 15, 25. The suggestion would be to use diamond layer 24 since the manufacturing process would be similar and the improvement in thermal conductivity much higher and especially high enough to be worth it in the case of diamond. In this set up high intensity laser 4 can be focused in a phosphor plate and white light can be generated in a very tiny spot. This solution will be sufficient by itself and won't need any additional active cooling. This is the safest way high intense white light at a micrometer spot can be created in a phosphor material. This will broaden the application field of white light.

The light recycling devices 5 according to the second and third embodiment of the invention (FIGS. 2 and 3) can be used for a reflective assembly of the light source 1 as well as a light-transmissive assembly. Within the transmissive assembly the heat sink 12 comprises a channel to enable the laser beam transilluminating the heat sink 12 and/or alternatively comprises a transparent heat sink 12 like a sapphire heat sink.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. Light source comprising a light-emitting device and a light recycling device, said light recycling device is located in an optical path of the light-emitting device, wherein the light recycling device comprises at least one light recycling member for changing at least one physical property of light passing it and at least one thermally conductive member capable of conducting heat generated in the light recycling member, said thermally conductive member is in thermal contact with the light recycling member and at least one heat sink.

2. Light source according to claim 1, wherein the light-emitting device is a high luminance light-emitting device with a luminance equal to or more than 1·10⁷ cd/m² and/or a laser.

3. Light source according to claim 1, wherein the change of the physical property of light is a wavelength converting of the light and/or a change of the polarization state of the light.

4. Light source according to claim 1, wherein the light recycling member is a phosphor plate and/or a phosphor film.

5. Light source according to claim 1, wherein the light-emitting device is a light-emitting device emitting blue light and/or ultraviolet light.

6. Light source according to claim 1, wherein the thermally conductive member is a light polarizing member.

7. Light source according to claim 6, wherein the light polarizing member is a wire-grid polarizer.

8. Light source according to claim 1, wherein the thermally conductive member of the light recycling device is formed as a thermally conductive layer arranged
on a surface of the light recycling member and/or
in between two different parts of the light recycling member.

9. Light source according to claim 8, wherein the thermally conductive layer is an at least partial reflective layer.

10. Light source according to claim 1, wherein the thermally conductive member is a diamond member and/or a sapphire member.

11. Light source according to claim 1, wherein the light recycling device further comprises the heat sink.

12. Light source according to claim 1, wherein the light source further comprises an optical element arranged between the light-emitting device and the light recycling device.

13. Light source according to claim 1, wherein the light recycling member and the thermally conductive member build a composite material of the light recycling device.

14. Light recycling device for changing at least one physical property of light passing it, wherein the light recycling device comprises at least one light recycling member, at least one thermally conductive member capable of conducting heat generated in the light recycling member, wherein said thermally conductive member is in thermal contact with the light recycling member and a heat sink.
